(19) United States
(12) Patent Application Publication
(10) Pub. No.: US 2025/0393308 A1
(43) Pub. Date: Dec. 25, 2025

(54) DISPLAY PANEL AND DISPLAY DEVICE

(71) Applicant: Tianma Advanced Display Technology Institute (Xiamen) Co.,Ltd., Xiamen (CN)

(72) Inventor: Yingying WU, Xiamen (CN)

(21) Appl. No.: 18/815,227

(22) Filed: Aug. 26, 2024

(30) Foreign Application Priority Data
Jun. 25, 2024 (CN) 202410826212.9

(51) Int. Cl. H01L 27/12; H01L 25/16; H01L 33/62

(52) U.S. Cl. CPC H10D 86/60; H01L 25/167; H10D 86/441; H10H 20/857

(57) ABSTRACT

A display panel includes: a substrate, sub-pixels; first power lines; first auxiliary electrodes; second power lines; and second auxiliary electrodes. One sub-pixel includes a first electrode, a second electrode, a pixel circuit and light-emitting elements. The first electrode is connected to one first power line, and adjacent first power lines are connected through one first auxiliary electrode. The second electrode is connected to one second power line through the pixel circuit, and adjacent second power lines are connected through one second auxiliary electrode. At least one sub-pixel includes M light-emitting elements connected in series, where M≥2. Two light-emitting elements are connected through an intermediate electrode. The intermediate electrode is disposed in a same layer as the first electrode and the second electrode, and is disposed in a same layer as one of the first power lines and the second power lines.

### CROSS-REFERENCE TO RELATED APPLICATION

This application claims the priority of Chinese Patent Application No. 202410826212.9, filed on Jun. 25, 2024, the content of which is incorporated herein by reference in its entirety.

### TECHNICAL FIELD

The present disclosure generally relates to the field of display technologies and, more particularly, relates to a display panel and a display device.

### BACKGROUND

A light-emitting diode (LED) can efficiently convert electrical energy into light energy, and has the characteristics of small size, long life, high efficiency, energy saving, rich colors, etc. With the continuous advancement of technology, LEDs have been widely used in the fields of photography, flat panel display, medical devices, etc. When used in the display field, some sub-pixels have the problem of low brightness, which affects the display effect.

### SUMMARY

One aspect of the present disclosure provides a display panel. The display panel includes: a substrate; a plurality of sub-pixels located on one side of the substrate, where one sub-pixel of the plurality of sub-pixels includes a first electrode, a second electrode, a pixel circuit and at least one light-emitting element; first power lines extending in a first direction and first auxiliary electrodes extending in a second direction, where the first direction and the second direction intersect, the first electrode is connected to one corresponding first power line, and two adjacent first power lines are connected through one corresponding first auxiliary electrode; and, second power lines extending in the first direction and second auxiliary electrodes extending in the second direction. The second electrode is connected to one corresponding second power line through the pixel circuit, and two adjacent second power lines are connected through one corresponding second auxiliary electrode, At least one sub-pixel of the plurality of sub-pixels includes M light-emitting elements connected in series, where M is an integer and M≥2; the M light-emitting elements includes a first light-emitting element and a second light-emitting element; the first light-emitting element and the second light-emitting element are connected through an intermediate electrode; the intermediate electrode, the first electrode and the second electrode are disposed in a same layer; and the intermediate electrode is disposed in a same layer as one of the first power lines and the second power lines.

Another aspect of the present disclosure provides a display device. The display device includes a display panel. The display panel includes: a substrate; a plurality of sub-pixels located on one side of the substrate, where one sub-pixel of the plurality of sub-pixels includes a first electrode, a second electrode, a pixel circuit and at least one light-emitting element; first power lines extending in a first direction and first auxiliary electrodes extending in a second direction, where the first direction and the second direction intersect, the first electrode is connected to one corresponding first power line, and two adjacent first power lines are connected through one corresponding first auxiliary electrode; and, second power lines extending in the first direction and second auxiliary electrodes extending in the second direction. The second electrode is connected to one corresponding second power line through the pixel circuit, and two adjacent second power lines are connected through one corresponding second auxiliary electrode, At least one sub-pixel of the plurality of sub-pixels includes M light-emitting elements connected in series, where M is an integer and M≥2; the M light-emitting elements includes a first light-emitting element and a second light-emitting element; the first light-emitting element and the second light-emitting element are connected through an intermediate electrode; the intermediate electrode, the first electrode and the second electrode are disposed in a same layer; and the intermediate electrode is disposed in a same layer as one of the first power lines and the second power lines.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary display panel consistent with various disclosed embodiments of the present disclosure.

FIG. 2 illustrates a cross-sectional view along an A-A′ direction of an exemplary display panel in FIG. 1, consistent with various disclosed embodiments of the present disclosure.

FIG. 3 illustrates an exemplary pixel circuit consistent with various disclosed embodiments of the present disclosure.

FIG. 4 illustrates another exemplary display panel consistent with various disclosed embodiments of the present disclosure.

FIG. 5 illustrates another exemplary display panel consistent with various disclosed embodiments of the present disclosure.

FIG. 6 illustrates another exemplary display panel consistent with various disclosed embodiments of the present disclosure.

FIG. 7 illustrates another exemplary display panel consistent with various disclosed embodiments of the present disclosure.

FIG. 8 illustrates another exemplary display panel consistent with various disclosed embodiments of the present disclosure.

FIG. 9 illustrates another exemplary display panel consistent with various disclosed embodiments of the present disclosure.

FIG. 10 illustrates another exemplary display panel consistent with various disclosed embodiments of the present disclosure.

FIG. 11 illustrates another exemplary display panel consistent with various disclosed embodiments of the present disclosure.

FIG. 12 illustrates another exemplary display panel consistent with various disclosed embodiments of the present disclosure.

FIG. 13 illustrates another exemplary display panel consistent with various disclosed embodiments of the present disclosure.

FIG. 14 illustrates another exemplary display panel consistent with various disclosed embodiments of the present disclosure.

FIG. 15 illustrates another exemplary display panel consistent with various disclosed embodiments of the present disclosure.

FIG. 16 illustrates another exemplary display panel consistent with various disclosed embodiments of the present disclosure.

FIG. 17 illustrates another exemplary display panel consistent with various disclosed embodiments of the present disclosure.

FIG. 18 illustrates another exemplary display panel consistent with various disclosed embodiments of the present disclosure.

FIG. 19 illustrates an exemplary local structure of a first sub-pixel in the exemplary display panel shown in FIG. 18 consistent with various disclosed embodiments of the present disclosure.

FIG. 20 illustrates a recovery state of the exemplary display panel in FIG. 18 consistent with various disclosed embodiments of the present disclosure.

FIG. 21 illustrates another recovery state of the exemplary display panel in FIG. 18 consistent with various disclosed embodiments of the present disclosure.

FIG. 22 illustrates another exemplary display panel consistent with various disclosed embodiments of the present disclosure.

FIG. 23 illustrates another exemplary display panel consistent with various disclosed embodiments of the present disclosure.

FIG. 24 illustrates another exemplary display panel consistent with various disclosed embodiments of the present disclosure.

FIG. 25 illustrates an exemplary display device consistent with various disclosed embodiments of the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

The present disclosure provides a display panel to at least partially alleviate the above problems. In the display panel provided by the present disclosure, at least one sub-pixel in the display panel may include at least two light-emitting elements connected in series, and the brightness of the at least one sub-pixel may be improved by using the light-emitting elements connected in series. A first power supply structure and a second power supply structure in the display panel may be respectively grid-shaped routings, which may improve the in-plane uniformity of the power supply signal. Further, an intermediate electrode connecting the two light-emitting elements in series may be disposed in a same layer as a first electrode and a second electrode of the at least one sub-pixel, and the intermediate electrode may be also disposed in the same layer as a power line. Therefore, the first electrode, the second electrode, the intermediate electrode and the two power supply structures may be manufactured by using two metal layers, which may reduce the film thickness of the display panel, reduce the process, and reduce the manufacturing cost.

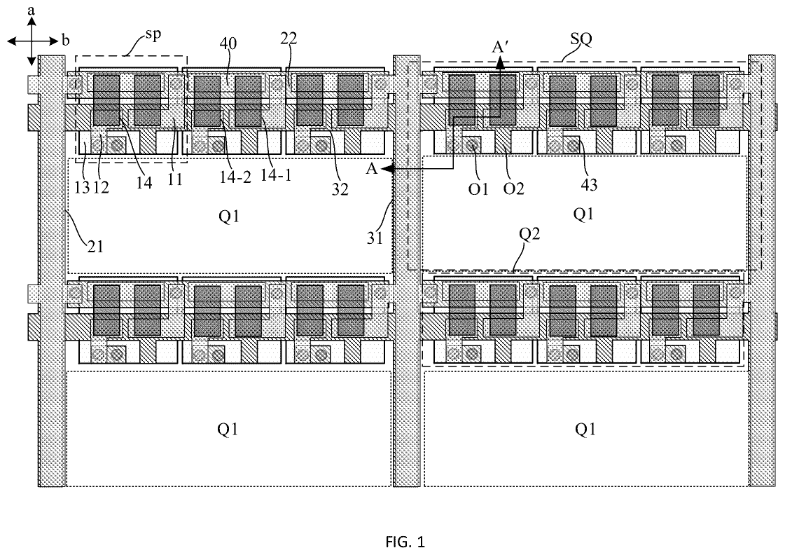

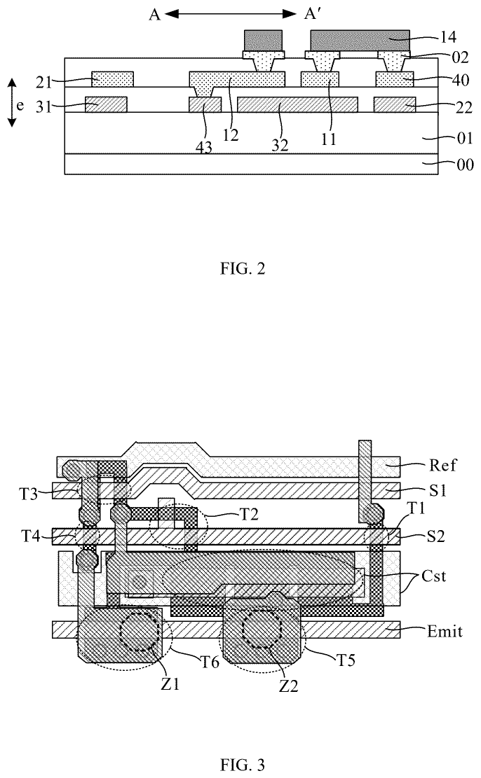

As shown in FIG. 1 which illustrates an exemplary display panel (a top view of the display panel at a position of four pixel regions SQ) consistent with various embodiments of the present disclosure and FIG. 2 illustrating a cross-sectional view along the A-A′ direction in FIG. 1, in one embodiment, the display panel may include a substrate 00 and a plurality of sub-pixels sp at a side of the substrate 00. Each sub-pixel sp may include a first electrode 11, a second electrode 12, a pixel circuit 13 and at least one light-emitting element 14. The at least one light-emitting element 14 may be an LED, such as a micro LED or a mini LED. FIG. 1 shows the pixel circuit 13 only as a block diagram, and in practice the pixel circuit 13 may include transistors and connecting lines. FIG. 2 shows a driving layer 01 where the pixel circuit 13 is located, and the first electrode 11, the second electrode 12 and the at least one light-emitting element 14 are located on a side of the driving layer 01 away from the substrate 00. FIG. 2 also shows a bonding layer 02, and a first terminal or the second terminal of the at least one light-emitting element 14 may be connected to the corresponding electrode through the bonding layer 02. FIG. 2 shows that one terminal of the at least one light-emitting element 14 is connected to the intermediate electrode 40 through the bonding layer 02, and the other terminal is connected to the first electrode 11 through the bonding layer 02.

As shown in FIG. 1, the display panel may further include first power lines 21 extending along a first direction a and first auxiliary electrodes 22 extending along a second direction b. The first direction a and the second direction b may intersect each other. For example, typically, the first direction a and the second direction b may be perpendicular to each other. The first electrode 11 may be connected to the first power line 21, and two adjacent first power lines 21 may be connected through one corresponding first auxiliary electrode 22. The display panel may further include second power lines 31 extending along the first direction a and second auxiliary electrodes 32 extending along the second direction b. The second electrode 12 may be connected to the second power line 31 through the pixel circuit 13, and two adjacent second power lines 31 may be connected through one corresponding second auxiliary electrode 32. FIG. 1 schematically shows connecting electrodes 43, where one second electrode 12 is connected to the pixel circuit 13 through one corresponding connecting electrode 43. It should be noted here that the term “extension” involved in the embodiments of the present disclosure refers to the extension direction of the power lines or the auxiliary electrodes, and does not limit the shape of the power lines or the auxiliary electrodes. For example, the line type of the first power lines 21 extending along the first direction a may be a straight line or a curve or a broken line. In the present embodiment, a first power supply structure may be formed by the first power lines 21 and the first auxiliary electrodes 22. From the perspective of the display panel as a whole, the first power supply structure may form a grid-like wiring, thereby improving the in-plane uniformity of the first power supply signal, reducing power consumption and improving display uniformity. Similarly, the second power supply lines 31 and the second auxiliary electrodes 32 may form a second power supply structure with a grid-like wiring, improving the in-plane uniformity of the second power supply signal. The structures in a same layer in FIG. 1 are filled with the same pattern.

At least one sub-pixel sp of the plurality of sub-pixels may include M light-emitting elements 14 connected in series, where M may be an integer and M≥2. The M light-emitting elements 14 may include a first light-emitting element 14-1 and a second light-emitting element 14-2. The first light-emitting element 14-1 and the second light-emitting element 14-2 may be connected through an intermediate electrode 40. The intermediate electrode 40, the first electrode 11, and the second electrode 12 may be located in the same layer, and the intermediate electrode 40 and one of the first power line 21 and the second power line 31 may be located in the same layer. In one embodiment shown in FIG. 1, the intermediate electrode 40 and the first power line 21 may be located in the same layer.

In the display panel provided by the present embodiment, at least one sub-pixel sp may include M light-emitting elements 14 connected in series, and the brightness of the at least one sub-pixel sp may be improved by using the design of the series structure. For example, when applied in high-brightness display, the at least one sub-pixel sp may be able to meet the high brightness requirement. Further, when the luminous efficiency of one single light-emitting element 14 in the at least one sub-pixel sp is low, the series structure may compensate for the problem that the brightness of the at least one sub-pixel sp is low because of the low luminous efficiency of one single light-emitting element 14. Also, the arrangement of the first power lines 21, the first auxiliary electrodes 22, the second power lines 31, and the second auxiliary electrodes 32 may improve the uniformity of the power signal in the plane, thereby improving the display uniformity. On the film structure of the display panel, one intermediate electrode 40 connecting the two series light-emitting elements 14 may be disposed the same layer as the original first electrode 11 and the second electrode 12, and the intermediate electrode 40 may be also disposed in the same layer as one of the first power lines 21 and the second power lines 31. The first auxiliary electrodes 22 may be disposed in the same layer as the first power lines 21, and the second auxiliary electrodes 32 may be disposed in the same layer as the second power lines 31. Or, the first auxiliary electrodes 22 and the second auxiliary electrodes 32 may be disposed in the same layer and located in the same layer as one of the first power lines and the second power lines. Therefore, the first electrode, the second electrode, the intermediate electrode and the two power structures may be manufactured using two metal layers, which may reduce the thickness of the display panel film layer, reduce the process flow, and reduce the manufacturing cost.

In one embodiment shown in FIG. 3 which illustrates an exemplary pixel circuit consistent with the present disclosure, the pixel circuit may include a data writing transistor T1, a compensation transistor T2, a gate reset transistor T3, an electrode reset transistor T4, a first light emission control transistor T5, a second light emission control transistor T6, a driving transistor Tm and a storage capacitor Cst. The region where the pixel circuit is located in the display panel may be also provided with a reset signal line Ref, a first scan line S1, a second scan line S2 and a light emission control line Emit. The gate reset transistor T3 and the electrode reset transistor T4 may be connected to the reset signal line Ref. A control terminal of the gate reset transistor T3 may be connected to the first scan line S1. A control terminal of the data writing transistor T1, a control terminal of the compensation transistor T2 and a control terminal of the electrode reset transistor T4 may be connected to the second scan line S2. The pixel circuit provided by the present embodiment may adopt an xTyC structure, where x and y are positive integers. That is, the pixel circuit may include x transistors and y capacitors. The embodiment shown in FIG. 3 illustrating the pixel circuit as a 7TIC structure is used as an example to describe the present disclosure.

FIG. 1 shows a first connection hole O1 and a second connection hole O2. The first connection hole O1 may be a connection via hole between the pixel circuit 13 and the connection electrode 43. The second connection hole O2 may be a connection via hole between the pixel circuit 13 and the second auxiliary electrode 32. The pixel circuit 13 may be connected to the second power line 31 via the second auxiliary electrode 32. In the structure of the pixel circuit 13 shown in FIG. 3, the position Z1 of the first connection hole O1 and the position Z2 of the second connection hole O2 are shown.

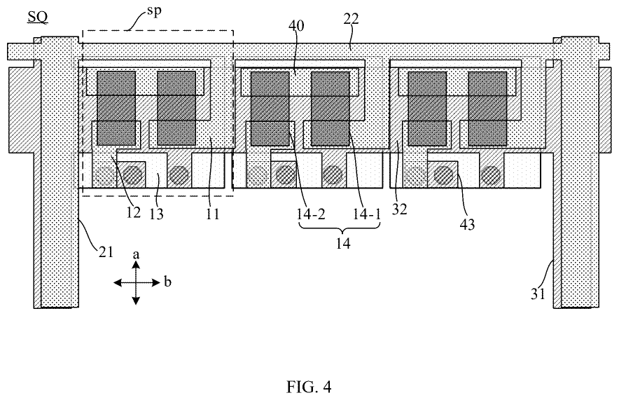

FIG. 4 is another schematic diagram of a display panel provided by the present disclosure, and FIG. 4 illustrates the location of a pixel region SQ. The structures located in the same layer are filled with the same pattern in FIG. 4. As shown in FIG. 4, in some embodiments, the first auxiliary electrodes 22 and the first power lines 21 may be disposed in the same layer, the second auxiliary electrodes 32 and the second power lines 31 may be disposed in the same layer. The intermediate electrodes 40, the first electrodes 11, the second electrodes 12, and the first power lines 21 may be disposed in the same layer. The first light-emitting element 14-1 and the second light-emitting element 14-2 in the sub-pixel sp may be connected in series through the intermediate electrode 40, and the first auxiliary electrode 22 and the intermediate electrode 40 may be disposed in the same layer. In this embodiment, the sub-pixel sp may include the first light-emitting element 14-1 and the second light-emitting element 14-2 connected in series, which may improve the brightness of the sub-pixel sp to meet the high brightness requirement. Further, the arrangement of the first power lines 21, the first auxiliary electrode 22, the second power lines 31, and the second auxiliary electrode 32 may improve the uniformity of the power signal in the plane, thereby improving the display uniformity.

In some embodiments, as shown in FIG. 2, the film layer where the first auxiliary electrode 22 is located may be disposed on a side of the film layer where the intermediate electrode 40 is located close to the substrate 00, and the first auxiliary electrode 22 and the second auxiliary electrode 32 may be disposed in the same layer. Along the direction e perpendicular to the plane where the substrate 00 is located, the first auxiliary electrode 22 and the intermediate electrode 40 may overlap. In conjunction with FIG. 1, in the sub-pixel sp, the intermediate electrode 40 may be used to realize the series connection of the two light-emitting elements 14, and the intermediate electrode 40 may be disposed in the same layer as the first electrode 11 and the second electrode 12. After the intermediate electrode 40 is added, it may be necessary to consider how to arrange the first auxiliary electrode 22. In the present embodiment, the first auxiliary electrode 22 and the intermediate electrode 40 may be disposed in different layers and may overlap each other, that is, the first auxiliary electrode 22 and the intermediate electrode 40 may not be located in the same layer and may be arranged side by side, thereby avoiding increasing the occupied width of the film layer where the intermediate electrode 40 is located in the pixel region SQ in the first direction a. For example, when the width of the second auxiliary electrode 32 in the first direction a is reduced at the same time, the first auxiliary electrode 22 and the second auxiliary electrode 32 may be arranged in the same layer, and by setting the width of the first auxiliary electrode 22 in the first direction a, it may be also possible to avoid increasing the occupied width of the film layer where the first auxiliary electrode 22 is located in the pixel region SQ in the first direction a. The design of the present embodiment may meet the wiring requirements of the first auxiliary electrode 22. Also, the first power supply structure may be set to be a grid shape to ensure the uniformity of the first power supply signal in the plane. The total width occupied by the power supply structure (including the first power supply structure and the second power supply structure) and the electrode structure (including the middle electrode, the first electrode and the second electrode) on the pixel circuit 13 in the first direction a may be prevented from being too large, which may save wiring space and meet the application requirements of high PPI (Pixels Per Inch, pixel density).

In some embodiments, the display panel provided by the present disclosure may be applied to transparent display. As shown in FIG. 1, one pixel region SQ may include a transmission region Q1 and a circuit region Q2. The light-emitting elements 14, the pixel circuit 13, the first auxiliary electrode 22 and the second auxiliary electrode 32 may all be disposed in the circuit region Q2. The first auxiliary electrode 22 and the intermediate electrode 40 may be arranged to overlap to avoid increasing the width of the circuit region Q2 in the first direction a, thereby not squeezing the width of the transmission region Q1 in the first direction a and ensuring the high transmittance requirement of the display panel.

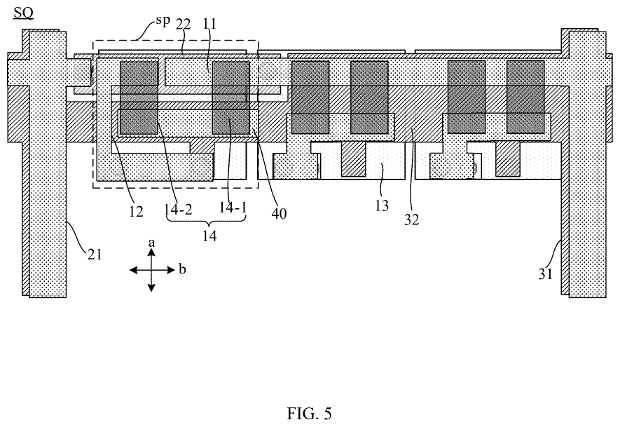

In one embodiment of FIG. 2, the first auxiliary electrode 22 and the intermediate electrode 40 may overlap in the direction e perpendicular to the plane where the substrate 00 is located. FIG. 5 is a schematic diagram of another display panel provided by the present disclosure and shows the location of one pixel region SQ. FIG5 is a top view of the display panel, and the top view direction is parallel to the direction perpendicular to the plane where the substrate 00 is located. As shown in FIG. 5, in some other embodiments, the first auxiliary electrode 22 and the second auxiliary electrode 32 may be disposed in the same layer. In the direction perpendicular to the plane where the substrate 00 is located, the second auxiliary electrode 32 and the intermediate electrode 40 in one sub-pixel sp may overlap. Therefore, the total width occupied by the power supply structure and the electrode structure on the pixel circuit 13 in the first direction a may also be prevented from increasing, which is beneficial to saving wiring space and meeting the application requirements of high PPI.

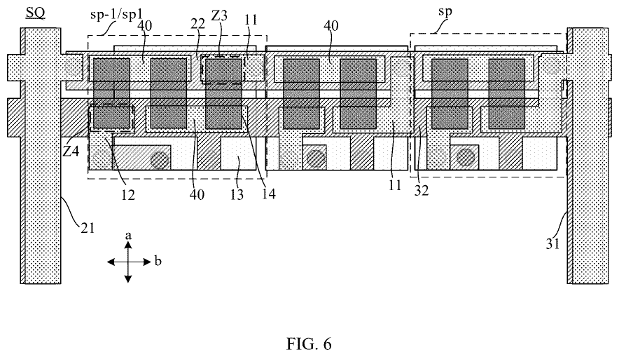

In some other embodiments shown in FIG. 6 which is a schematic diagram of another exemplary display panel provided by the present disclosure, in one sub-psp-1, M-3, that is, three light-emitting elements 14 may be connected in series. The sub-pixel sp-1 may include two intermediate electrodes 40. One of the intermediate electrodes 40 may overlap with the first auxiliary electrode 22, and the other intermediate electrode 40 may overlap with the second auxiliary electrode 32.

In some embodiments, as shown in FIG. 1, the first auxiliary electrode 22 may overlap with the intermediate electrode 40, and the orthographic projection of the first auxiliary electrode 22 on the plane where the substrate is located may cover the orthographic projection of the intermediate electrode 40 on the plane where the substrate 00 is located. Since the two light-emitting elements 14 connected in series need to be connected through the intermediate electrode 40, the corresponding electrodes on the light-emitting elements 14 may need to overlap with the intermediate electrode 40 accordingly. The arrangement of the present embodiment may make the film layer below the intermediate electrode 40 a whole piece of the first auxiliary electrode 22, which is beneficial to the flatness of the intermediate electrode 40 and ensures the flatness of the bonding region. The yield of the bonding process of the light-emitting elements 14 may be also improved.

As shown in FIG. 5, in some embodiments, the second auxiliary electrode 32 may overlap with the intermediate electrode 40 of the sub-pixel sp. And, the orthographic projection of the second auxiliary electrode 32 on the plane where the substrate 00 is located may cover the orthographic projection of the intermediate electrode 40 on the plane where the substrate 00 is located. This configuration may ensure that there is a whole second auxiliary electrode 32 under the intermediate electrode 40, which is beneficial to the flatness of the intermediate electrode 40, thereby improving the yield of the bonding process of the light-emitting elements 14.

As shown in FIG. 6, in the sub-pixel sp-1, one of the intermediate electrodes 40 may overlap with the first auxiliary electrode 22, and the other of the intermediate electrodes 40 may overlap with the second auxiliary electrode 32. The orthographic projection of the first auxiliary electrode 22 on the plane where the substrate is located may cover the orthographic projection of the corresponding intermediate electrode 40 on the plane where the substrate 00 is located, and the orthographic projection of the second auxiliary electrode 32 on the plane where the substrate 00 is located may cover the orthographic projection of the corresponding intermediate electrode 40 on the plane where the substrate 00 is located.

As shown in FIG. 1, the sub-pixel sp may also include the connecting electrode 43, and the second electrode 12 may be connected to the pixel circuit 13 through the connecting electrode 43. FIG. 1 also schematically shows a first connecting hole O1 between the connecting electrode 43 and the pixel circuit 13. The connecting electrode 43 and the first auxiliary electrode 22 may be disposed in the same layer. That is, the connecting electrode 43, the first auxiliary electrode 22, and the second auxiliary electrode 32 may be disposed in the same layer. Since the second electrode 12 needs to be connected to the pixel circuit 13, when the second electrode 12 and the pixel circuit 13 are directly connected via a hole, the depth of the via hole on the plane e perpendicular to the substrate 00 will be too large, affecting the yield of the via hole connection and the size of the punch hole (referring to the region size of the hole). The connecting electrode 43 may be arranged between the second electrode 12 and the pixel circuit 13, which may reduce the depth of the via hole, improve the yield of the via hole connection, and also reduce the size of the punch hole. Further, the connecting electrode 43 may be formed in the film layer where the first auxiliary electrode 22 and the second auxiliary electrode 32 are located, which does not increase the process of the display panel and is conducive to reducing the production cost.

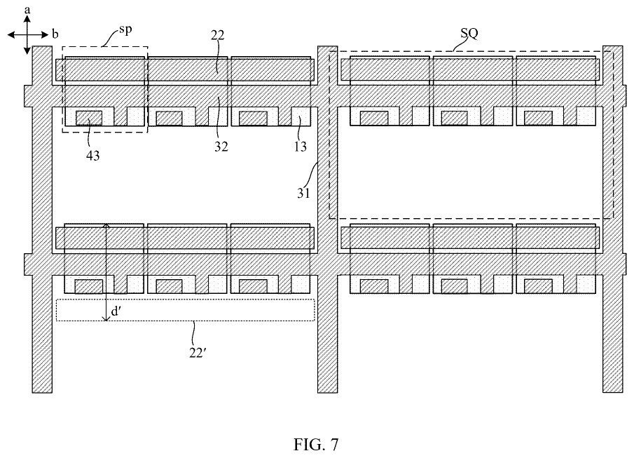

FIG. 7 is a schematic diagram of another display panel provided by the present disclosure, and only the first auxiliary electrode 22, the second auxiliary electrode 32, the connecting electrode 43, the second power line 31, and the pixel circuit 13 in FIG. 1 are retained in FIG. 7. As shown in FIG. 7, in one embodiment, one pixel region SQ may include at least three sub-pixels sp. In the pixel region SQ, the connecting electrode 43 and the first auxiliary electrode 22 may be respectively disposed at two sides of the second auxiliary electrode 32. Reasonable arrangement of the relative positions of the first auxiliary electrode 22, the second auxiliary electrode 32, and the connecting electrode 43 located in the same film layer may reduce the space occupied by the circuit region in the pixel region SQ in the first direction a. For example, assuming that the connecting electrode 43 is located between the first auxiliary electrode 22 and the second auxiliary electrode 32, the first auxiliary electrode 22 may be located at the position 22′ indicated by the dotted line in FIG7. In combination with the structure of the pixel circuit 13 shown in FIG. 3, the connection position between the pixel circuit 13 and the connection electrode 43 may be fixed, and the connection position between the pixel circuit 13 and the second auxiliary electrode 32 may be fixed, such that the relative position between the pixel circuit 13 and the connection electrode 43 and the second auxiliary electrode 32 may be fixed. When the first auxiliary electrode 22 is located at the position 22′ encircled by the dotted line, the total width occupied by the circuit region in the first direction a may be d′. It can be seen that compared with the embodiment of the present disclosure, the width occupied by the circuit region in the first direction a is increased.

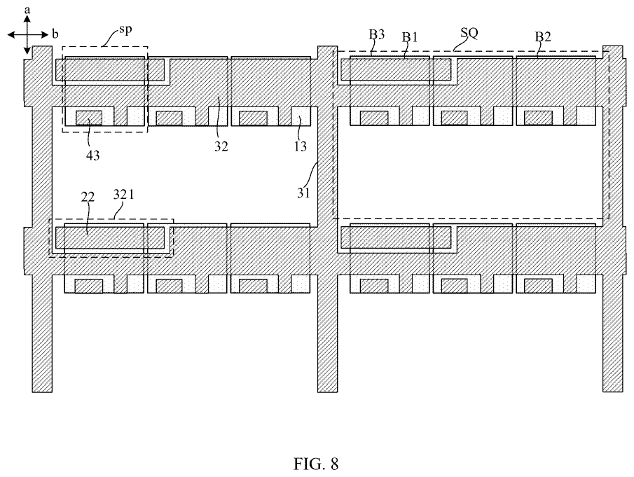

FIG. 8 is a schematic diagram of another display panel provided by the present disclosure, and only the first auxiliary electrode 22, the second auxiliary electrode 32, the connecting electrode 43, the second power line 31, and the pixel circuit 13 are shown in FIG. 8. As shown in FIG8, in some other embodiments, in the pixel region SQ, the connecting electrode 43 and the first auxiliary electrode 22 may be respectively located on two sides of the second auxiliary electrode 32. The second auxiliary electrode 32 may have a notch 321, and the first auxiliary electrode 22 may be located in the notch 321. In this embodiment, the relatively arrangement position of the first auxiliary electrode 22 and the second auxiliary electrode 32 may be set to meet the requirements of differential setting of sub-pixels sp in the pixel region SQ. For example, some of the sub-pixels sp in one pixel region SQ may include M light-emitting elements 14 connected in series, and some others of the sub-pixels sp may include one light-emitting element 14.

In some embodiments, the first auxiliary electrode 22 may be located in the notch 321 of the second auxiliary electrode 32, and the edge of the first auxiliary electrode 22 away from the connecting electrode 43 and the edge of the second auxiliary electrode 32 away from the connecting electrode 43 may be substantially flush. This arrangement may avoid increasing the total width of the first auxiliary electrode 22 and the second auxiliary electrode 32 in the first direction a, and avoid compressing the size of the transmission region in transparent display.

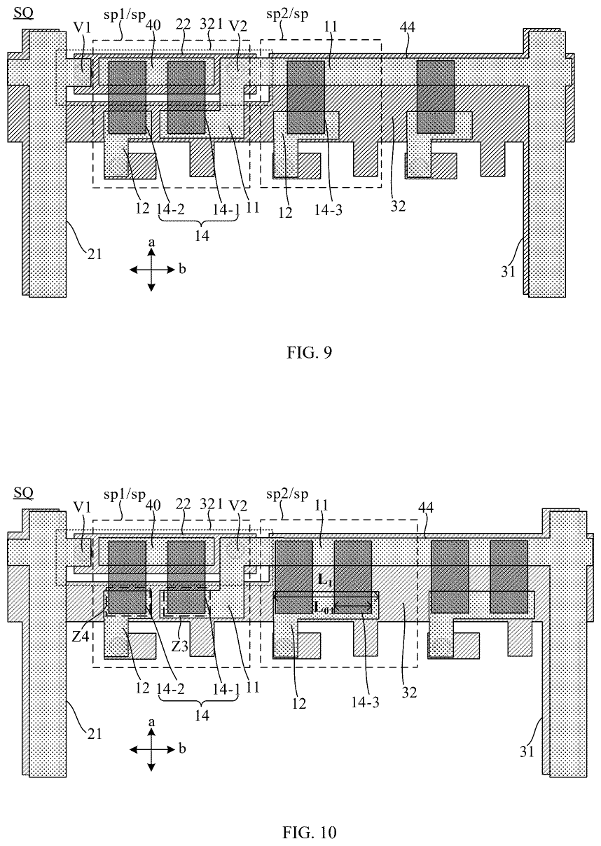

FIG. 9 is a schematic diagram of another display panel provided the present disclosure. FIG. 9 illustrates the location of one pixel region SQ, and does not show the pixel circuit 13 in the pixel region SQ. As shown in FIG. 9, in some embodiments, the second auxiliary electrode 32 may have a notch 321, and the first auxiliary electrode 22 may be located the notch 321. The second power line 31 may be disposed in the same layer as the second auxiliary electrode 32 and the first auxiliary electrode 22. The first power line 21 and the intermediate electrode 40 may be disposed in the same layer. That is, the first power line 21 and the first auxiliary electrode 22 may be disposed in different layers. The display panel may also include a third auxiliary electrode 44 extending along the second direction b. The third auxiliary electrode 44 may be disposed in the same layer as the first power line 21 and may be directly connected to the first power line 21. FIG. 9 is a top view, and it can be seen from FIG. 9 that the third auxiliary electrode 44 may overlap with the second auxiliary electrode 32 in the direction perpendicular to the plane where the substrate 00 is located. One terminal of the first auxiliary electrode 22 may be connected to the first power line 21 through the first via hole V1, and the other terminal may be connected to the third auxiliary electrode 44 through the second via hole V2. In this embodiment, the first auxiliary electrode 22 may be disposed in the notch 321 of the second auxiliary electrode 32, and the first auxiliary electrode 22 and the third auxiliary electrode 44 may be connected between two adjacent first power lines 21, such that the first power structure in the display panel may form a grid-like wiring. Further, the third auxiliary electrode 44 may be arranged to be directly connected to the first power line 21, and the electrode structure and the two power structures may be formed by two film layers, which may reduce the thickness of the display panel film layer, reduce the process, and reduce the production cost.

Further, since the first auxiliary electrode 22 is arranged in the notch 321 of the second auxiliary electrode 32, the maximum width of the second auxiliary electrode 32 in the first direction a may be larger, thereby reducing the resistance of the second auxiliary electrode 32, which is beneficial to the voltage drop of the second power structure. Moreover, the third light-emitting element 14-3 in the second sub-pixel sp2 may be connected to the third auxiliary electrode 44, and the third auxiliary electrode 44 may be directly connected to the first power line 21 instead of being connected via a hole, thereby reducing the number of holes in the display panel.

In some embodiments, as shown in FIG. 9, the sub-pixel sp may include first sub-pixel sp1 and second sub-pixels sp2. one first sub-pixel sp1 may include M (one embodiment with M=2 is illustrated in FIG. 9) light-emitting elements 14 connected in series, and the light-emitting elements 14 in one second sub-pixel sp2 may include a third light-emitting element 14-3. The first terminal of the third light-emitting element 14-3 may be connected to the third auxiliary electrode 44, and the second terminal of the third light-emitting element 14-3 may be connected to the second electrode 12. In this embodiment, the third auxiliary electrode 44 may be multiplexed as the first terminal 11 of the second sub-pixel sp2, and the light-emitting path where the third light-emitting element 14-3 in the second sub-pixel sp2 is located may only include one light-emitting element 14. It can be understood that the light-emitting path where the M light-emitting elements 14 connected in series in the first sub-pixel sp1 are located may include the M light-emitting elements 14, and one first electrode 11 and one second electrode 12 may be located in one light-emitting through hole. This embodiment may realize differentiated setting of the first sub-pixels sp1 and the second sub-pixels sp2. When there is a difference in luminous efficiency between the single light-emitting element 14 in the first sub-pixel sp1 and the single light-emitting element 14 in the second sub-pixel sp2, the series structure may be used to enhance the brightness of the first sub-pixels sp1, thereby compensating for the difference in luminous efficiency between the two kinds of sub-pixels.

FIG. 10 is another schematic diagram of a display panel provided by the present disclosure. As shown in FIG. 10, in another embodiment, in at least one second sub-pixel sp2, the length of the second electrode 12 along the second direction b may be L₁, and the length of the third light-emitting element 14-3 in the second direction b may be L₀₁, and L₁>2*L₀₁. In this embodiment, the third auxiliary electrode 44 extending along the second direction b may be multiplexed as the first electrode 11 in the at least one second sub-pixels sp2. To ensure that the third auxiliary electrode 44 is connected to the first auxiliary electrode 22 via the via hole, the third auxiliary electrode 44 may need to extend to a position overlapping with the first auxiliary electrode 22. Therefore, as shown in FIG. 10, the third auxiliary electrode 44 may overlap with the second electrode 12 in the second sub-pixel sp2 along the first direction a. In the present embodiment, the length of the second electrode 12 along the second direction b may be relatively large, and the second electrode 12 may be bonded to at least two third light-emitting elements 14-3. Correspondingly, in the region where the second sub-pixel sp2 is located, the third auxiliary electrode 44 may be bonded to two third light-emitting elements 14-3, that is, at least two third light-emitting elements 14-3 may be bonded in the second sub-pixel sp2. The embodiment shown In FIG. 10 where the second sub-pixel sp2 includes two third light-emitting elements 14-3 is used as an example to illustrate the present disclosure, and does not limit the scope of the present disclosure. In some embodiments, two third light-emitting elements 14-3 may be directly bonded to the second sub-pixel sp2. When one third light-emitting element 14-3 is damaged during use, the other may be able to emit light to ensure the light emission of the second sub-pixel sp2. In other embodiments, the length design of the second electrode 12 may be equivalent to setting a redundant position on the second sub-pixel sp2. One third light-emitting element 14-3 may be bonded in the second sub-pixel sp2 first. When the second sub-pixel sp2 cannot emit light normally, an additional third light-emitting element 14-3 may be bonded at the redundant position to repair the second sub-pixel sp2.

In one embodiment, the sub-pixels sp may include first color sub-pixels and second color sub-pixels of different luminous colors, and the luminous wavelength of the first color sub-pixels may be larger than the luminous wavelength of the second color sub-pixels. The first sub-pixels sp1 may include the first color sub-pixels, and the second sub-pixels sp2 may include the second color sub-pixels. Generally, the shorter the luminous wavelength of one sub-pixel sp, the higher the energy, and the higher the luminous efficiency. Therefore, the luminous efficiency of the light-emitting elements in the first color sub-pixels may be less than the luminous efficiency of the light-emitting elements in the second color sub-pixels. This embodiment may improve the brightness by using the design of the series structure in the first sub-pixels sp1 to compensate for the difference in luminous efficiency between light-emitting elements of different colors.

In one embodiment, the first sub-pixels sp1 may include red sub-pixels, and the second sub-pixels sp2 may include green sub-pixels and blue sub-pixels. In one pixel region SQ, one red sub-pixel may include M light-emitting elements 14 connected in series, one green sub-pixel may include at least one third light-emitting element 14-3, and one blue sub-pixel may include at least one third light-emitting element 14-3. This setting may improve the brightness of the red sub-pixels to compensate for the brightness difference between the red sub-pixels and other color sub-pixels.

In some embodiments, the number of the light-emitting elements 14 in one first sub-pixel sp1 may be larger than the number of the light-emitting elements 14 in one second sub-pixel sp2. For example, in one embodiment, M=2, that is, one first sub-pixel sp1 may include two light-emitting elements, and one second sub-pixel sp2 may include one light-emitting element 14.

In some embodiments, as shown in FIG. 7, the first auxiliary electrode 22 and the second auxiliary electrode 32 may penetrate the pixel region SQ in the second direction b. For example, the first auxiliary electrode 22 penetrating the pixel region SQ may be understood as the first auxiliary electrode 22 extending from one end of the pixel region SQ to the other end of the pixel region SQ in the second direction b. The first auxiliary electrode 22 and the second auxiliary electrode 32 may be disposed in the same layer, and only one of the first power line 21 and the second power line 31 may be disposed in the same layer as the first auxiliary electrode 22 and the second auxiliary electrode 32. In this embodiment, one of the first auxiliary electrode 22 and the second auxiliary electrode 32 may need to be connected to one corresponding power line through a via hole that penetrates the insulating layer. As shown in FIG. 7, in one embodiment, the second power line 31 and the second auxiliary electrode 32 may be disposed in the same layer, and the first power line 21 may need to be connected to the first auxiliary electrode 22 through a via hole that penetrates the insulating layer. In this embodiment, the first auxiliary electrode 22 and the second auxiliary electrode 32 may be arranged to penetrate the pixel region SQ in the second direction b, and the via holes connecting the auxiliary electrodes to the power lines may not be arranged between adjacent sub-pixels sp in the pixel region SQ, to avoid increasing the spacing distance between adjacent sub-pixels sp in the pixel region SQ.

FIG. 11 is another schematic diagram of a display panel provided by the present disclosure, and FIG. 11 schematically shows the location of one pixel region SQ and does not show the pixel circuit in the pixel region SQ. As shown in FIG. 11, in some embodiments, the second power line 31 and the second auxiliary electrode 32 may be located in the same layer, and may be in contact and connected. The first power line 21 and the intermediate electrode 40 may be located in the same layer. The first auxiliary electrode 22 may be connected to the first power line 21 through the third via hole V3. This embodiment may use two metal film layers to produce an electrode structure and two power structures, without increasing the process of the display panel, which is conducive to reducing the production cost.

In other embodiments shown in FIG. 12 which is another schematic diagram of a display panel provided by the present disclosure and schematically shows the location of a pixel region SQ without showing the pixel circuit in the pixel region SQ, the first power line 21 and the first auxiliary electrode 22 may be located in the same layer, and the two may be in contact and connected. The second power line 31 and the intermediate electrode 40 may be located in the same layer. The second auxiliary electrode 32 may be connected to the second power line 31 through the fourth via hole V4. This embodiment may utilize two metal film layers to produce an electrode structure and two power supply structures without increasing the process steps of the display panel, which is beneficial for reducing production costs.

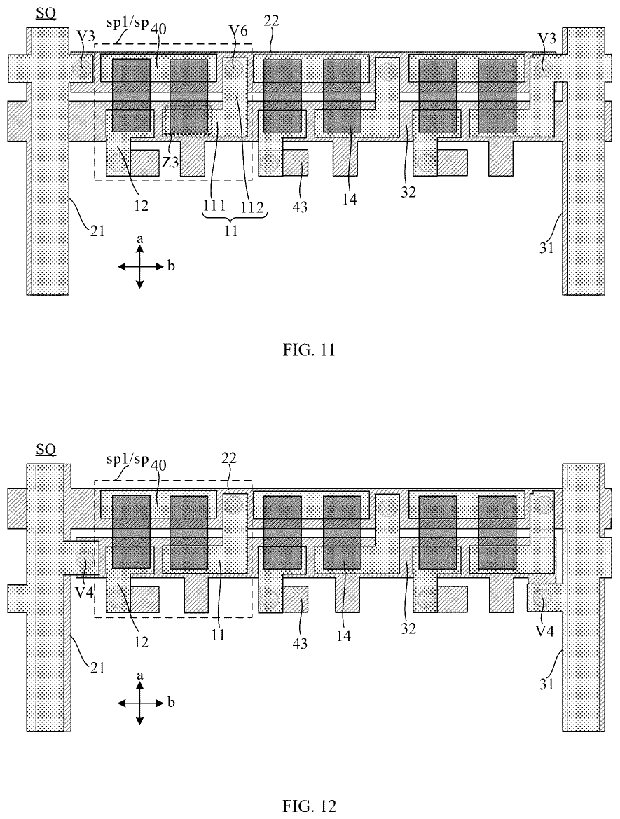

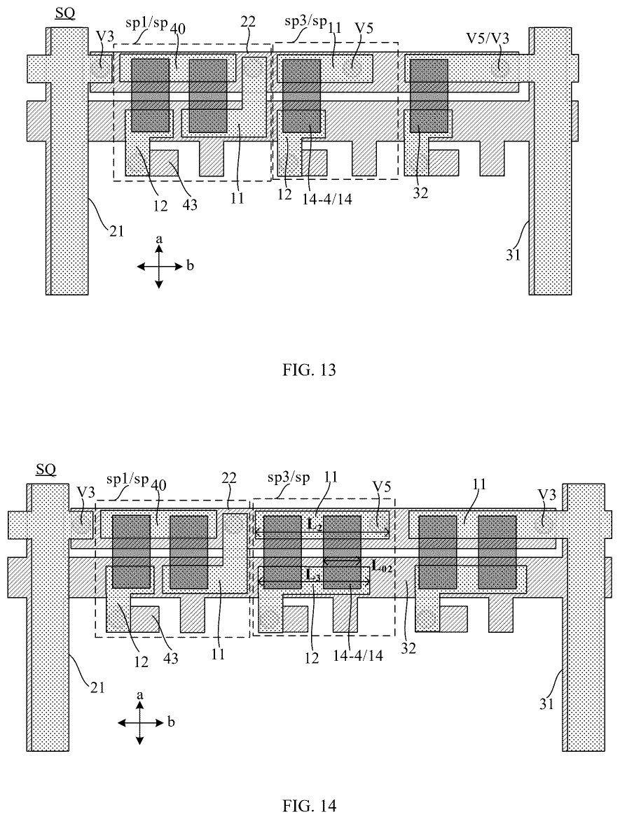

In other embodiments shown in FIG. 13 which is another schematic diagram of a display panel provided by the present disclosure and schematically shows the location of a pixel region SQ, the sub-pixel sp may include a first sub-pixel sp1 and a third sub-pixel sp3. The first sub-pixel sp1 may include M light-emitting elements 14 connected in series. Taking M=2 as an example, the light-emitting element 14 in the third sub-pixel sp3 may include a fourth light-emitting element 14-4. The first electrode of the fourth light-emitting element 14-4 may be connected to the first electrode 11, and the second electrode may be connected to the second electrode 12. FIG. 13 is a top view of the display panel. As shown in FIG. 13, in the third sub-pixel sp3: along the direction perpendicular to the plane where the substrate 00 is located, the first electrode 11 may overlap with the first auxiliary electrode 22 and may be connected through the fifth via hole V5, and the fifth via hole V5 may not overlap with the fourth light-emitting element 14-4. This embodiment may realize the differentiated setting of the first sub-pixel sp1 and the third sub-pixel sp3. When there is a difference in luminous efficiency between the single light-emitting element 14 in the first sub-pixel sp1 and the single light-emitting element 14 in the third sub-pixel sp3, the series structure may be used to improve the brightness of the first sub-pixel sp1, thereby compensating for the difference in luminous efficiency between the two sub-pixels.

FIG. 13 shows that a pixel region SQ may include a first sub-pixel sp1 and two third sub-pixels sp3, and the first electrode 11 in the third sub-pixel sp3 located in the middle may need to be connected to the first auxiliary electrode 22 through the fifth via hole V5. The first electrode 11 of the third sub-pixel sp3 adjacent to the first power line 21 may be connected to the first auxiliary electrode 22 through the fifth via hole V5, that is, the first electrode 11 of the third sub-pixel sp3 adjacent to the first power line 21 may be directly connected to the first power line 21, and the first power line 21 may be connected to the first auxiliary electrode 22 through the third via hole V3. In this embodiment, the first auxiliary electrode 22 and the second auxiliary electrode 32 may penetrate the pixel region SQ in the second direction b, and the widths of the first auxiliary electrode 22 and the second auxiliary electrode 32 in the second direction b may be substantially the same.

In some embodiments shown in FIG. 14 which is a schematic diagram of another display panel provided by the present disclosure, in at least one third sub-pixel sp3, the length of the first electrode 11 along the second direction b may be L2, the length of the second electrode 12 along the second direction b may be L3, and the length of the fourth light-emitting element 14 in the second direction b may be L02, where L2>2*L02, L3>2*L02. In this embodiment, at least two fourth light-emitting elements 14-4 may be bonded in one third sub-pixel sp3. FIG. 14 illustrates one embodiment where the third sub-pixel sp3 includes two fourth light-emitting elements 14-4. In some embodiments, two fourth light-emitting elements 14-4 may be directly bonded to the third sub-pixel sp3. When one fourth light-emitting element 14-4 is damaged during use, the other may emit light to ensure the light emission of the third sub-pixel sp3. In other embodiments, the length design of the first electrode 11 and the second electrode 12 may be equivalent to setting a redundant position on the third sub-pixel sp3. First, one fourth light-emitting element 14-4 may be bonded in the third sub-pixel sp3. When the third sub-pixel sp3 cannot emit light normally, an additional fourth light-emitting element 14-4 may be bonded at the redundant position to repair the third sub-pixel sp3.

In one embodiment, the sub-pixels sp may include first color sub-pixels and second color sub-pixels of different luminous colors, and the luminous wavelength of the first color sub-pixels may be larger than the luminous wavelength of the second color sub-pixels. The first sub-pixels sp1 may include the first color sub-pixels, and the third sub-pixels sp3 may include the second color sub-pixels. Generally, the shorter the luminous wavelength of one sub-pixel sp, the higher the energy, and the higher the luminous efficiency. Therefore, the luminous efficiency of the light-emitting elements in the first color sub-pixels may be less than the luminous efficiency of the light-emitting elements in the second color sub-pixels. This embodiment may improve the brightness by using the design of the series structure in the first sub-pixels sp1 to compensate for the difference in luminous efficiency between light-emitting elements of different colors.

In one embodiment, the first sub-pixels sp1 may include red sub-pixels, and the third sub-pixels sp3 may include green sub-pixels and blue sub-pixels. In one pixel region SQ, one red sub-pixel may include M light-emitting elements 14 connected in series, one green sub-pixel may include at least one fourth light-emitting element 14-4, and one blue sub-pixel may include at least one fourth light-emitting element 14-4. This setting may improve the brightness of the red sub-pixels to compensate for the brightness difference between the red sub-pixels and other color sub-pixels.

In some embodiments, the number of the light-emitting elements 14 in one first sub-pixel sp1 may be larger than the number of the light-emitting elements 14 in one third sub-pixel sp3. For example, in one embodiment, M=2, that is, one first sub-pixel sp1 may include two light-emitting elements, and one third sub-pixel sp3 may include one light-emitting element 14.

In one embodiment, as shown in FIG. 10 or FIG. 14, the sub-pixels sp may include a first sub-pixel sp1, and the first sub-pixel sp1 may include M light-emitting elements 14 connected in series. The M light-emitting elements 14 may be arranged along the second direction b. In one light-emitting element 14 among the M light-emitting elements 14 a first terminal may be connected to the first electrode 11, and a second terminal may be connected to the middle electrode 40. In another light-emitting element 14, a second terminal may be connected to the second electrode 12, and the first terminal may be connected to the intermediate electrode 40. That is, the light-emitting path formed by the M light-emitting elements 14 connected in series may include a first electrode 11 and a second electrode 12. FIG. 10 and FIG. 14 both take M=2 as an example. In addition, the sub-pixel sp-1 in FIG. 6 is also the first sub-pixel sp1, and M=3 in the sub-pixel sp-1. The M light-emitting elements 14 in the first sub-pixel sp1 may be arranged along the second direction b, and the direction from the first terminal of each light-emitting element 14 to the second terminal may be parallel to the first direction a. Therefore, it may be easy to set the arrangement of the first electrode 11, the second electrode 12, and the intermediate electrode 40 in the first sub-pixel sp1 to rationally utilize space and reduce the region occupied by the circuit region.

In some embodiments, in the first sub-pixel sp1, M may be an even number. As shown in FIG. 10, for example, in one embodiment, M=2, and, in the first sub-pixel sp1, the first electrode 11 may include a first connection region Z3. The first connection region Z3 may be connected to the first terminals of the light-emitting elements 14, and it may be understood that the region in the first electrode 11 overlapping with the light-emitting elements 14 in FIG. 10 may be the first connection region Z3. The second electrode 12 may include a second connection region ZA, and the second connection region Z4 may be connected to the second terminals of the light-emitting elements 14. It may be understood that the region in the second electrode 12 overlapping with the light-emitting elements 14 in FIG. 10 may be the second connection region ZA. From the top view shown in FIG. 10, along the direction perpendicular to the plane where the substrate 00 is located, the first connection region Z3 and the second connection region 74 may overlap with the second auxiliary electrode 32 respectively. The first connection region Z3 and the second connection region ZA may be bonding regions on the first electrode 11 and the second electrode 12, respectively. The present embodiment may make the first connection region Z3 and the second connection region ZA below the whole second auxiliary electrode 32, which is conducive to the flatness of the first connection region Z3 and the second connection region ZA, thereby improving the yield of the bonding process of the light-emitting element 14.

In other embodiments, in the first sub-pixel sp1, M may be an odd number. As shown in FIG. 6, taking M=3 as an example, in the first sub-pixel sp1, the first electrode 11 may include a first connection region Z3, and the first connection region Z3 may be connected to the first terminals of the light-emitting elements 14. The second electrode 12 may include a second connection region ZA, and the second connection region Z4 may be connected to the second terminals of the light-emitting elements 14. From the top view shown in FIG. 6, it may be seen that along the direction perpendicular to the plane where the substrate 00 is located, the first connection region Z3 may overlap with the first auxiliary electrode 22, and the second connection region ZA may overlap with the second auxiliary electrode 32. The present embodiment may ensure the flatness of the first connection region Z3 and the second connection region ZA, thereby improving the yield of the bonding process of the light-emitting elements 14.

It can be seen from the top view of FIG. 11 that, in the first sub-pixel sp1, along the direction perpendicular to the plane where the substrate is located, the intermediate electrode 40 may overlap with the first auxiliary electrode 22; and along the first direction a, the intermediate electrode 40 may overlap with the main body 111 in the first electrode 11, and the intermediate electrode 40 may overlap with the second electrode 12.

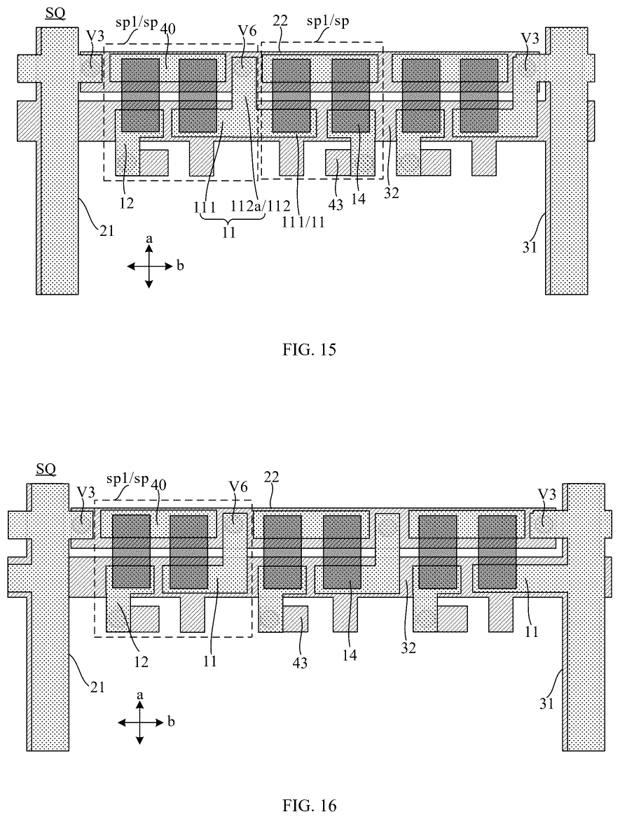

In other embodiments shown in FIG. 15 which is a schematic diagram of another display panel provided by the present disclosure, the connecting portion 112 may include a first connecting portion 112a, and the first connecting portion 112a may connect the two main bodies 111 of two adjacent first electrodes 11. That is, the first electrodes 11 in two adjacent first sub-pixels sp1 may share the first connecting portion 112a. Such a setting may reduce the number of connecting portions 112 set in the pixel regions SQ and the number of sixth via holes V6, thereby reducing the length occupied by the pixel regions SQ in the second direction b, which is beneficial to improving PPI.

As shown in FIG. 15, in two adjacent first sub-pixels sp1 that share the first connecting portion 112a, the two second electrodes 12 may be symmetrical about the axis along the first direction a, and the left and right relative positions of the connecting electrode 43 and the protrusion 322 of the second auxiliary electrode 32 may be different. For example, in the first of the first sub-pixels sp1 arranged from left to right, the connecting electrode 43 may be on the left and the protrusion 322 may be on the right. In the second of the first sub pixels sp2 arranged from left to right, the connecting electrode 43 may be on the right and the protrusion 322 may be on the left. Combining the relevant descriptions in the above-mentioned FIG. 1 and FIG. 3, it may be known that the protrusion 322 is the part on the second auxiliary electrode 32 that is connected to the pixel circuit 13 by via holes. In the embodiment shown in FIG. 15, the structures of the two pixel circuits 13 in the two adjacent first sub-pixels sp1 may be designed to be symmetrical about the axis along the first direction a, to cooperate to realize that the two first electrodes 11 share the first connecting portion 112a.

In other embodiments shown in FIG. 16 which is a schematic diagram of another display panel provided by the present disclosure, at least one of the first sub-pixels sp1 may be adjacent to the first power line 21. For example, the first sub-pixel sp1 from the right in the figure may be adjacent to the first power line 21, and the first electrode 11 of the first sub-pixel sp1 may be located in the same layer and directly connected to the first power line 21. In this embodiment, the first power line 21 may be located in the same layer as the intermediate electrode 40 and the first electrode 11, and the first electrode 11 may be directly connected to the first power line 21 at an appropriate position.

In some other embodiments shown in FIG. 16 which is a schematic diagram of another display panel provided by the present disclosure, at least one of the first sub-pixels sp1 may be adjacent to the first power line 21. For example, one first sub-pixel sp1 from the right in the figure may be adjacent to the first power line 21, and the first electrode 11 of the first sub-pixel sp1 may be located in the same layer as and directly connected to the first power line 21. In this embodiment, the first power line 21 may be located in the same layer as the intermediate electrode 40 and the first electrode 11, and the first electrode 11 may be directly connected to the first power line 21 at an appropriate position.

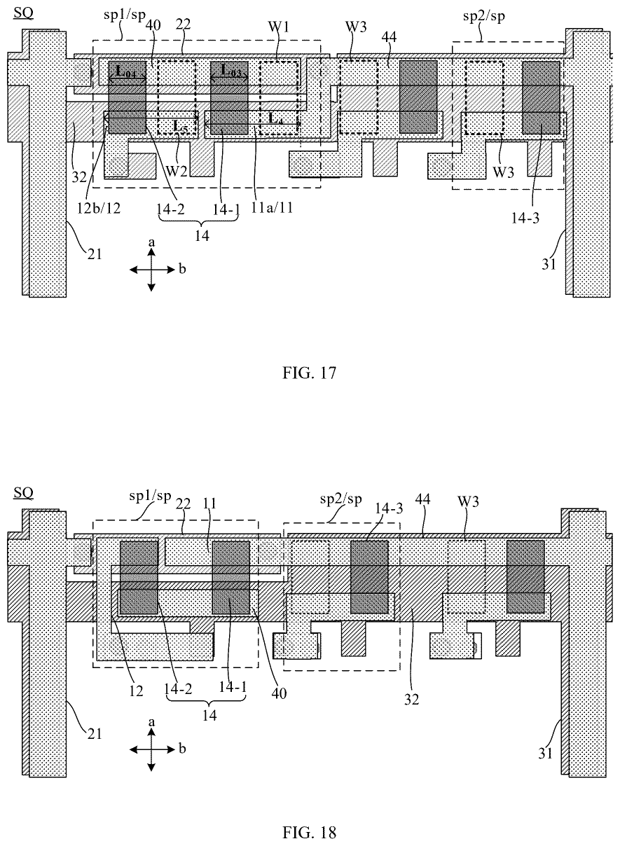

In some embodiments shown in FIG. 17 which is a schematic diagram of another display panel provided by the present disclosure, in at least one first sub-pixel sp1, the first terminal of the first light-emitting element 14-1 may be connected to the first electrode 11, the second terminal may be connected to the intermediate electrode 40, the first terminal of the second light-emitting element 14-2 may be connected to the intermediate electrode 40, and the second terminal may be connected to the second electrode 12. It can be seen from the top view of FIG. 17 that the intermediate electrode 40 may overlap with the first auxiliary electrode 22 in the direction perpendicular to the plane where the substrate 00 is located. The portion where the first electrode 11 overlaps with the intermediate electrode 40 along the first direction a may be the first main body 11a, the length of the first main body 11a along the second direction b may be LA, and the width of the first light-emitting element 14-1 in the second direction b may be L03, where L4>2*L03. The length of the second electrode 12 along the second direction b may be L5, and the width of the second light-emitting element 14-2 in the second direction b may be L04, where L5>2*L04. In this embodiment, the lengths of the first main body 11a in the first electrode 11 and the second main body 12b in the second electrode 12 may be designed respectively, which is equivalent to reserving a redundant position in the first sub-pixel sp1, and the first sub-pixel sp1 may be repaired by using the redundant position. A first redundant position W1 may be set for the first light-emitting element 14-1, and when the first light-emitting element 14-1 cannot emit light, a light-emitting element 14 may be bonded to the first redundant position W1 to ensure that the series light-emitting through holes in the first sub-pixel sp1 are able to work normally. A second redundant position W2 may be set for the second light-emitting element 14-2. When the second light-emitting element 14-2 cannot emit light, a light-emitting element 14 may be bonded to the second redundant position W2 to ensure that the series light-emitting through holes in the first sub-pixel sp1 are able to work normally.

As shown in FIG. 17, a third redundant position W3 may be provided in the second sub-pixel sp2. When the third light-emitting element 14-3 cannot emit light, a light-emitting element 14 may be bonded to the third redundant position W3 to ensure that the second sub-pixel sp2 is able to work normally.

In some embodiments, in at least one first sub-pixel sp1, the first terminal of the first light-emitting element 14-1 may be connected to the first electrode 11, and the second terminal may be connected to the intermediate electrode 40. The first terminal of the second light-emitting element 14-2 may be connected to the intermediate electrode 40, and the second terminal may be connected to the second electrode 12. The portion where the first electrode 11 overlaps with the intermediate electrode 40 along the first direction a may be the first main body 11a, the length of the first main body 11a along the second direction b may be L4, and the width of the first light-emitting element 14-1 in the second direction b may be L03, where L4>2*L03. In this embodiment, a redundant position may be provided for the first light-emitting element 14-1. When the first light-emitting element 14-1 cannot emit light, a light-emitting element 14 may be bonded to the corresponding redundant position to repair the first sub-pixel sp1, to ensure that the series light-emitting through holes in the first sub-pixel sp1 are able to work normally.

In some other embodiments, in at least one first sub-pixel sp1, the first terminal of the first light-emitting element 14-1 may be connected to the first electrode 11, and the second terminal may be connected to the intermediate electrode 40. The first terminal of the second light-emitting element 14-2 may be connected to the intermediate electrode 40, and the second terminal may be connected to the second electrode 12. The length of the second electrode 12 along the second direction b may be L5, and the width of the second light-emitting element 14-2 in the second direction b may be L04, where L5>2*L04. A redundant position may be set for the second light-emitting element 14-2. When the second light-emitting element 14-2 cannot emit light, a light-emitting element 14 may be bonded to the corresponding redundant position W2 to ensure that the series light-emitting through holes in the first sub-pixel sp1 are able to work normally.

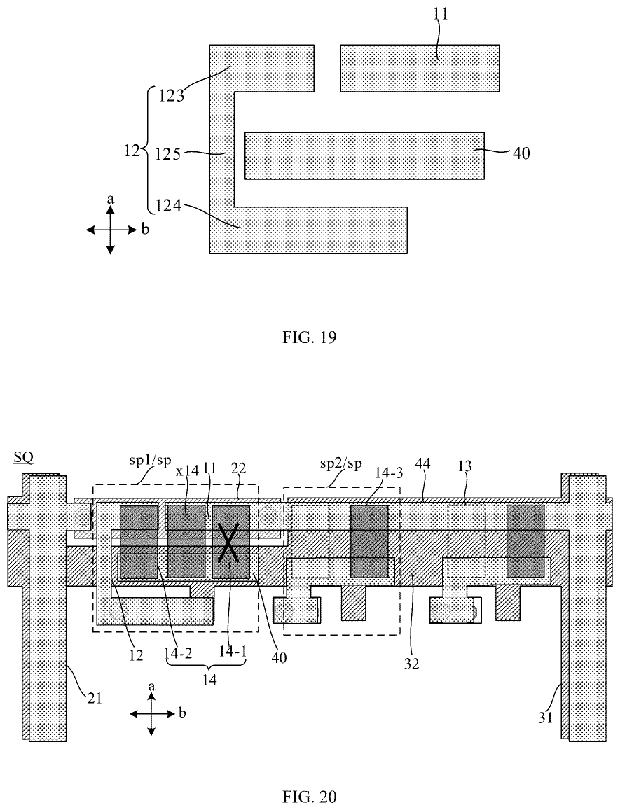

FIG. 18 may be a schematic diagram of another display panel provided by the present disclosure, and FIG.19 may be a schematic diagram of a local structure in the first sub-pixel in FIG. 18. FIG. 19 schematically illustrates the first electrode 11, the second electrode 12, and the intermediate electrode 40 in the first sub-pixel sp1. As shown in FIG. 18, in some embodiments, in at least one first sub-pixel sp1, the first terminal of the first light-emitting element 14-1 may be connected to the first electrode 11, and the second terminal may be connected to the intermediate electrode 40. The first terminal of the second light-emitting element 14-2 may be connected to the intermediate electrode 40, and the second terminal may be connected to the second electrode 12. It can be seen from the top view of FIG. 18 that, in the direction perpendicular to the plane where the substrate may be located, the intermediate electrode 40 may overlap with the second auxiliary electrode 32, and the first electrode 11 may overlap with the first auxiliary electrode 22. In conjunction with FIG. 19, the second electrode 12 may include a first section 123, a second section 124 and a middle portion 125. The middle portion 125 may be connected to the first section 123 and the second section 124 at two ends in the first direction a, respectively. The length of the second section 124 along the second direction b may be larger than the length of the first section 123. The first section 123 may overlap with the first auxiliary electrode 22 in the direction perpendicular to the plane where the substrate may be located. The intermediate electrode 40 may be located between the first section 123 and the second section 124. The edge of the intermediate electrode 40 away from the middle portion 125 along the second direction b may exceed the second section 124. The first electrode 11 may overlap with the second section along the first direction a. FIG. 18 shows that the first electrode 11 may be a part of the third auxiliary electrode 44. In other embodiments, the first electrode 11 may also be an isolated electrode block.

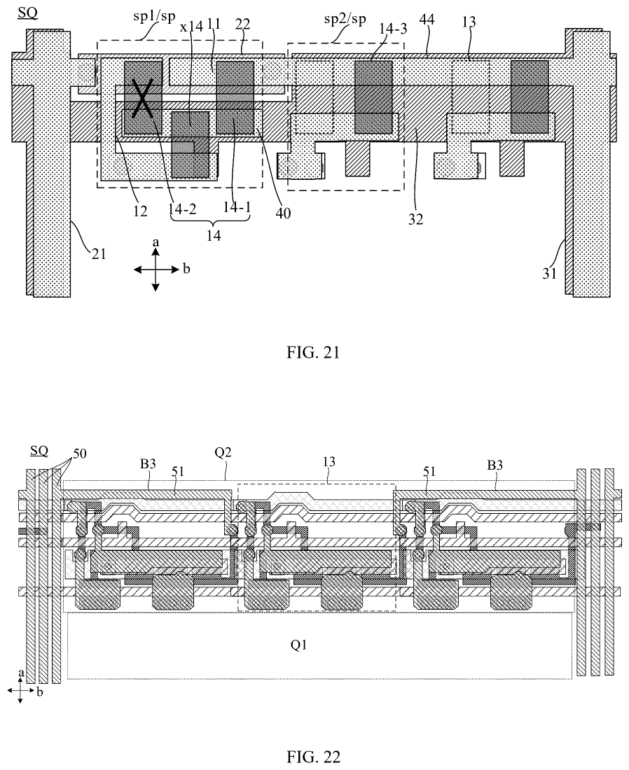

In the embodiment of FIG. 18, a redundant position may be provided in the first sub-pixel sp1, and the first sub-pixel sp1 may be able to be repaired. FIG. 20 is a schematic diagram of a repair state in the embodiment of FIG. 18, and FIG. 21 is a schematic diagram of another repair state in the embodiment of FIG. 18. As shown in FIG. 20, in the first sub-pixel sp1, a fourth redundant position may be formed in the region where the first electrode 11 and the intermediate electrode 40 overlap along the first direction a. When the first light-emitting element 14-1 cannot emit light, a repair light-emitting element x14 may be bonded at the fourth redundant position, and the repair light-emitting element x14 may be connected in series with the second light-emitting element 14-2, such that the series light-emitting path in the first sub-pixel sp1 is able to work normally. As shown in FIG. 21, in the first sub-pixel sp1, a fifth redundant position may be formed in the region where the intermediate electrode 40 and the second subsection 124 of the second electrode 12 overlap along the first direction a. When the second light-emitting element 14-2 cannot emit light, a repair light-emitting element x14 may be bonded at the fourth redundant position, and the repair light-emitting element x14 may be connected in series with the first light-emitting element 14-1, such that the series light-emitting path in the first sub-pixel sp1 is able to work normally. In the present embodiment, the first electrode 11, the second electrode 12 and the intermediate electrode 40 in the first sub-pixel sp1 may be designed to reserve a redundant position in the region where the first sub-pixel sp1 is located, and the redundant position may be used to selectively repair the defects of the first light-emitting element 14-1 or the second light-emitting element 14-2 to ensure that the first sub-pixel sp1 emits light normally. Further, the redundant position may occupy a width in the second direction b that is approximately equal to the width of one light-emitting element 14, and have little effect on the width of the pixel region SQ in the second direction b.

Further, in the embodiment of FIG. 18, one pixel region SQ may include one first sub-pixel sp1 and one second sub-pixel sp2, and the second sub-pixel sp2 may be provided with a third redundant position W3. The third redundant position W3 may be bonded with a light-emitting element to repair the second sub-pixel sp2.

In the present embodiment, the sub-pixels may include first color sub-pixels, second color sub-pixels, and third color sub-pixels with different luminous colors. The first sub-pixels sp1 may include at least one of the first color sub-pixels, the second color sub-pixels, or the third color sub-pixels. The first color sub-pixels, the second color sub-pixels, and the third color sub-pixels may be respectively one of a red sub-pixel, a green sub-pixel, and a blue sub-pixel.

In some embodiments, the sub-pixels of the three colors of red, green, and blue may be all the first sub-pixels sp1, as shown in FIG. 4, FIG. 11, FIG. 12, FIG. 15, or FIG. 16, and the electrode structures of the three sub-pixels sp in one pixel region SQ may be basically the same, and the three sub-pixels sp may respectively include M light-emitting elements 14 connected in series. In this embodiment, the sub-pixels of three colors may have high brightness to meet the high brightness display requirements.

In some embodiments, the sub-pixels of three colors may include M light-emitting elements 14 connected in series, respectively, and the number of light-emitting elements 14 in the red sub-pixels may be larger than the number of light-emitting elements 14 in the green sub-pixels and the blue sub-pixels. As shown in FIG6, the first sub-pixel sp from left to right may be a red sub-pixel, and the second and third sub-pixels may be green sub-pixels and blue sub-pixels, respectively.

In some embodiments, the red sub-pixel may include M light-emitting elements 14 connected in series, and the light-emitting paths in the green sub-pixel and the blue sub-pixel each may include only one light-emitting element 14. As shown in the embodiment of FIG. 9, in one pixel region SQ, the first sub-pixel sp1 may be a red sub-pixel, and the other two second sub-pixels sp2 may be green sub-pixels and blue sub-pixels. In another embodiment, as shown in the embodiment of FIG. 13, in one pixel region SQ, the first sub-pixel sp1 may be a red sub-pixel, and the other two third sub-pixels sp3 may be green sub-pixels and blue sub-pixels.

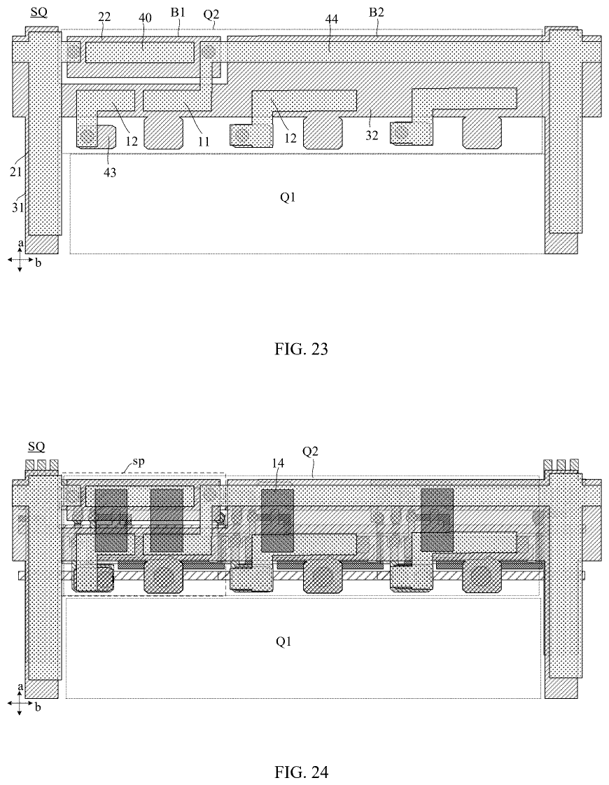

FIG. 22 is a schematic diagram of another display panel provided by the present disclosure, FIG. 23 is a schematic diagram of another display panel provided by the present disclosure, and FIG. 24 is a schematic diagram of another display panel provided by the present disclosure. FIG. 22 illustrates three pixel circuits 13 in one pixel region SQ, FIG. 23 illustrates a first power supply structure and a second power supply structure in one pixel region SQ, and FIG. 24 is a schematic diagram of the superposition of FIG. 22 and FIG. 23. As shown in FIG. 24, the pixel region SQ may include a transmission region Q1 and a circuit region Q2, and the light-emitting element 14, the pixel circuit 13, the first auxiliary electrode 22 and the second auxiliary electrode 32 may be disposed in the circuit region Q2. The pixel circuit 13 may be located on the side of the first auxiliary electrode 22 and the second auxiliary electrode 32 close to the substrate (not shown in FIG. 24). The structure of the pixel circuit 13 in FIG. 22 may be understood by referring to the relevant description in the embodiment of FIG. 3.

FIG. 22 illustrates a first connecting line 51 in the circuit region Q2, and the first connecting line 51 may be connected between the data line 50 and the data writing transistor T1. The first connecting line 51 may need to be set in the first and third pixel circuits 13 from left to right. In one pixel region SQ, the edge of the first connecting line 51 away from the transmission region Q1 may be the third edge B3 of the pixel circuit 13 where it is located. As shown in FIG. 23, the first auxiliary electrode 22 may have a first edge B1, and the second auxiliary electrode 32 may have a second edge B2. In the pixel region SQ, along the first direction a, the edge of the first auxiliary electrode 22 away from the transmission region Q1 may be the first edge B1, and the edge of the second auxiliary electrode 32 away from the transmission region Q1 may be the second edge B2. As shown in FIG. 24, the first edge B1 may be substantially flush with the third edge B3, and the second edge B2 may be substantially flush with the third edge B3. In the circuit region Q2, the transistors and connecting lines in the pixel circuit 13 may be reasonably wired, and the pixel circuit 13 may affect the occupied width of the circuit region Q2 in the first direction a. The first auxiliary electrode 22, the second auxiliary electrode 32 and the pixel circuit 13 may be disposed in different layers, the first edge B1 may be substantially flush with the third edge B3, and the second edge B2 may be substantially flush with the third edge B3, which may avoid affecting the size of the transmission region Q1.

In some other embodiments, in one pixel region SQ: along the first direction a, the edge of the first auxiliary electrode 22 away from the transmission region Q1 may be the first edge B1, the edge of the second auxiliary electrode 32 away from the transmission region Q1 may be the second edge B2, and the edge of the pixel circuit 13 away from the transmission region Q1 may be the third edge B3. Along the first direction a, the third edge B3 may exceed the first edge B1 and the second edge B2. FIG. 8 shows a simplified schematic diagram of the pixel circuit 13, and the first edge B1, the second edge B2 and the third edge B3 are marked. As shown in FIG. 8, along the first direction a, the third edge B3 may exceed the first edge B1 and the second edge B2. This setting may ensure that the design of the first auxiliary electrode 22 and the second auxiliary electrode 32 does not affect the size of the transmission region Q1.

The relative position relationship of the first auxiliary electrode 22 and the second auxiliary electrode 23 in FIG. 23 may be the same as that of the embodiment of FIG. 8 above. When the relative position relationship between the first auxiliary electrode 22 and the second auxiliary electrode 23 in the display panel adopts the design in the embodiment of FIG. 7, the first edge B1 may be set substantially flush with the third edge B3, or the third edge B3 may be set beyond the first edge and the second edge, thereby ensuring that the size of the transmission region Q1 may be not affected.

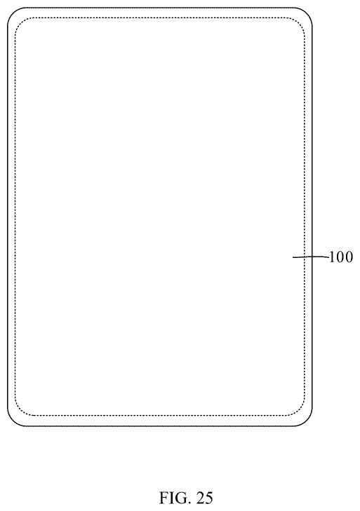

The present disclosure also provides a display device. As shown in FIG. 25, in one embodiment, the display device may include any display panel provided by various embodiments of the present disclosure. The display device provided by the present disclosure may be any electronic device with a display function, such as a cell phone, a tablet, a computer, a television, or a smart wearable product.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising:
a substrate and a plurality of sub-pixels located on one side of the substrate, wherein one sub-pixel of the plurality of sub-pixels includes a first electrode, a second electrode, a pixel circuit and at least one light-emitting element;
first power lines extending in a first direction and first auxiliary electrodes extending in a second direction, wherein: the first direction and the second direction intersect, the first electrode is connected to one corresponding first power line, and two adjacent first power lines are connected through one corresponding first auxiliary electrode;
second power lines extending in the first direction and second auxiliary electrodes extending in the second direction, wherein the second electrode is connected to one corresponding second power line through the pixel circuit, and two adjacent second power lines are connected through one corresponding second auxiliary electrode, p1 wherein:
at least one sub-pixel of the plurality of sub-pixels includes M light-emitting elements connected in series, where M is an integer and M≥2;
the M light-emitting elements includes a first light-emitting element and a second light-emitting element;
the first light-emitting element and the second light-emitting element are connected through an intermediate electrode;
the intermediate electrode, the first electrode and the second electrode are disposed in a same layer; and
the intermediate electrode is disposed in a same layer as one of the first power lines and the second power lines.

2. The display panel according to claim 1, wherein:
a film layer where the first auxiliary electrodes are located is on a side of a film layer where the intermediate electrode is located close to the substrate;
the first auxiliary electrodes and the second auxiliary electrodes are located in a same layer; and
along a direction perpendicular to the plane where the substrate is located, the intermediate electrode and one corresponding first auxiliary electrode overlap, and/or the intermediate electrode and one corresponding second auxiliary electrode overlap.

3. The display panel according to claim 2, wherein:
an orthographic projection of one first auxiliary electrode on the plane where the substrate is located covers an orthographic projection of one corresponding intermediate electrode on the plane where the substrate is located, and/or an orthographic projection of one second auxiliary electrode on the plane where the substrate is located covers an orthographic projection of one corresponding intermediate electrode on the plane where the substrate is located.

4. The display panel according to claim 2, wherein:
the sub-pixel further includes a connecting electrode, wherein: the second electrode is connected to the pixel circuit via the connecting electrode, and the connecting electrode and one corresponding first auxiliary electrode are located in the same layer.

5. The display panel according to claim 4, wherein:
the display panel includes pixel regions, and one pixel region includes at least three sub-pixels; and
in one pixel region, the connecting electrode and one corresponding first auxiliary electrode are respectively located on two sides of one corresponding second auxiliary electrode.

6. The display panel according to claim 5, wherein:
in the pixel region, the second auxiliary electrode has a notch, and the first auxiliary electrode is located in the notch.

7. The display panel according to claim 6, wherein:
the second power lines and the second auxiliary electrodes are located in the same layer, and the first power lines and the intermediate electrodes are located in the same layer;
the display panel further includes third auxiliary electrodes extending along the second direction;
one third auxiliary electrode and one corresponding first power line are located in a same layer and are directly connected;
along the direction perpendicular to the plane where the substrate is located, one third auxiliary electrode overlaps with one corresponding second auxiliary electrode; and
in one first auxiliary electrode, one end is connected to one corresponding first power line through a first via hole, and the other end is connected to one corresponding third auxiliary electrode through a second via hole.

8. The display panel according to claim 7, wherein:
the plurality of sub-pixels includes first sub-pixels and second sub-pixels;
one first sub-pixel includes M light-emitting elements connected in series; and
one second sub-pixel includes a third light-emitting element, wherein a first terminal of the third light-emitting element is connected to one corresponding third auxiliary electrode, a second terminal of the third light-emitting element is connected to one corresponding second electrode, and the third auxiliary electrode is multiplexed as a first terminal of the second sub-pixel.

9. The display panel according to claim 8, wherein:
in at least one second sub-pixel, a length of the second electrode along the second direction is L₁, a length of the third light-emitting element along the second direction is L₀₁, and L₁>2*L₀₁.

10. The display panel according to claim 8, wherein:
the plurality of sub-pixels includes first color sub-pixels and second color sub-pixels with different luminous colors, wherein a luminous wavelength of the first color sub-pixels is larger than a luminous wavelength of the second color sub-pixels; and
the first sub-pixels include the first color sub-pixels, and the second sub-pixels include the second color sub-pixels.

11. The display panel according to claim 5, wherein:
in one pixel region, the first auxiliary electrode and the second auxiliary electrode penetrate the pixel region in the second direction.

12. The display panel according to claim 11, wherein:
the second power line and the second auxiliary electrode are located in a same layer, the first power line and the intermediate electrode are located in a same layer, and the first auxiliary electrode is connected to the first power line through a third via hole;
or,
the first power line and the first auxiliary electrode are located in a same layer, the second power line and the intermediate electrode are located in a same layer, and the second auxiliary electrode is connected to the second power line through a fourth via hole.

13. The display panel according to claim 11, wherein:
the plurality of sub-pixels includes first sub-pixels and third sub-pixels;
one first sub-pixel includes M light-emitting elements connected in series, and
one third sub-pixel includes a fourth light-emitting element, wherein: a first terminal of the fourth light-emitting element is connected to the first electrode, a second terminal of the fourth light-emitting element is connected to the second electrode, and, along a direction perpendicular to the plane where the substrate is located, the first electrode overlaps with the first auxiliary electrode and is connected to the first auxiliary electrode through a fifth via hole.

14. The display panel according to claim 13, wherein:
in at least one of the third subpixels, a length of the first electrode along the second direction is L2, a length of the second electrode along the second direction is L3, and a length of the fourth light-emitting element in the second direction is L02, where L2>2* L02, L3>2* L02.

15. The display panel according to claim 13, wherein:
the plurality of sub-pixels includes first color sub-pixels and second color sub-pixels with different luminous colors, wherein a luminous wavelength of the first color sub-pixels is larger than a luminous wavelength of the second color sub-pixels; and
the first sub-pixels include the first color sub-pixels, and the third sub-pixels include the second color sub-pixels.

16. The display panel according to claim 2, wherein:
the plurality of sub-pixels includes first sub-pixels;
one first sub-pixel includes M light-emitting elements connected in series;
the M light-emitting elements are arranged along the second direction;
in one of the M light-emitting elements, a first terminal is connected to the first electrode, and a second terminal is connected to the middle electrode; and
in another one of the M light-emitting elements, a second terminal is connected to the second electrode, and a first terminal is connected to the intermediate electrode.

17. The display panel according to claim 16, wherein:
the first electrode includes a first connection region which is connected to the first terminal of one corresponding light-emitting element;
the second electrode includes a second connection region which is connected to the second terminal of one corresponding light-emitting element; and
in the first sub-pixel, M is an even number, wherein: along the direction perpendicular to the plane where the substrate is located, the first connection region and the second connection region overlap with the second auxiliary electrode respectively; or, in the first sub-pixel, M is an odd number, wherein: along the direction perpendicular to the plane where the substrate is located, the first connection region overlaps with the first auxiliary electrode and the second connection region overlaps with the second auxiliary electrode.

18. The display panel according to claim 16, wherein, wherein:
the first electrode includes a first connection region which is connected to the first electrode of the corresponding light-emitting element; and
in the first sub-pixel, M is an even number, and the first electrode includes a main body extending along the first direction and a connection portion extending along the second direction, wherein: the main body includes the first connection region, and the connection portion is connected to the first auxiliary electrode through a sixth via hole; the main body and the connection portion are connected to form an L-shaped structure, and a portion of the intermediate electrode is located at a corner of the L-shaped structure.

19. The display panel according to claim 1, wherein:
the display panel includes pixel regions, and one pixel region includes a transmission region and a circuit region, wherein: the light-emitting elements, the pixel circuit, the first auxiliary electrode and the second auxiliary electrode are located in the circuit region, and the pixel circuit is located on a side of the first auxiliary electrode and the second auxiliary electrode close to the substrate; and
in one pixel region, along the first direction, an edge of the first auxiliary electrode away from the transmission region is a first edge, an edge of the second auxiliary electrode away from the transmission region is a second edge, and an edge of the pixel circuit away from the transmission region is a third edge, wherein: the first edge and/or the second edge is flush with the third edge; or, along the first direction, the third edge exceeds the first edge and the second edge.

20. A display device, comprising a display panel, wherein:
the display panel includes:
a substrate and a plurality of sub-pixels located on one side of the substrate, wherein one sub-pixel of the plurality of sub-pixels includes a first electrode, a second electrode, a pixel circuit and at least one light-emitting element;
first power lines extending in a first direction and first auxiliary electrodes extending in a second direction, wherein: the first direction and the second direction intersect, the first electrode is connected to one corresponding first power line, and two adjacent first power lines are connected through one corresponding first auxiliary electrode; and
second power lines extending in the first direction and second auxiliary electrodes extending in the second direction, wherein the second electrode is connected to one corresponding second power line through the pixel circuit, and two adjacent second power lines are connected through one corresponding second auxiliary electrode,
wherein:
at least one sub-pixel of the plurality of sub-pixels includes M light-emitting elements connected in series, where M is an integer and M≥2;
the M light-emitting elements includes a first light-emitting element and a second light-emitting element;
the first light-emitting element and the second light-emitting element are connected through an intermediate electrode;
the intermediate electrode, the first electrode and the second electrode are disposed in a same layer; and
the intermediate electrode is disposed in a same layer as one of the first power lines and the second power lines.
